(19) United States
(12) Patent Application Publication
(10) Pub. No.: US 2024/0397607 A1
(43) Pub. Date: Nov. 28, 2024

(54) COMPUTER COOLING SYSTEM WITH DEFORMABLE DUCTS

(71) Applicant: INTERNATIONAL BUSINESS MACHINES CORPORATION, ARMONK, NY (US)

(72) Inventors: DUSTIN DEMETRIOU, New York, NY (US); Sadegh Khalili, Poughkeepsie, NY (US); Yuanchen Hu, Peekskill, NY (US)

(21) Appl. No.: 18/324,289

(22) Filed: May 26, 2023

(51) Int. Cl. H05K 1/02; G06F 1/20; H05K 7/20

(52) U.S. Cl. CPC H05K 1/0212; G06F 1/20; H05K 7/20263; H05K 7/20272; H05K 7/20281

(57) ABSTRACT

A computing system includes a motherboard with an array of card connectors, circuit boards connected to the array of card connectors, wherein the circuit boards include electronic components, constraining walls positioned around the circuit boards to form a housing over the motherboard, and expandable ducts. One of the expandable ducts is positioned in contact with one of the electronic components and constrained by a constraining wall when expanded, and each of the expandable ducts includes an inlet, an outlet, and a fluid flow path from the inlet to the outlet that is parallel to other fluid flow paths of other expandable ducts.

### BACKGROUND

The present disclosure relates to computing systems, and more specifically, to closed-circuit fluid cooling systems for circuit boards.

Many computing systems include circuit boards with electronic components that generate heat during operation. In order to better cool these components, various cooling structures can be thermally connected thereto. However, many computing systems have many different circuit boards, and many circuit boards have components with varying sizes, heights, and locations. Thereby, it can be difficult to design, manufacture, inventory, and install traditional solid cooling structures for each of the different circuit boards in a computing system.

### SUMMARY

According to one embodiment of the present disclosure, a computing system includes a motherboard with an array of card connectors, circuit boards connected to the array of card connectors, wherein the circuit boards include electronic components, constraining walls positioned around the circuit boards to form a housing over the motherboard, and expandable ducts. One of the expandable ducts is positioned in contact with one of the electronic components and constrained by a constraining wall when expanded, and each of the expandable ducts includes an inlet, an outlet, and a fluid flow path from the inlet to the outlet that is parallel to other fluid flow paths of other expandable ducts.

According to one embodiment of the present disclosure, a heat transfer system includes a pump, a heat exchanger fluidly connected to the pump, and a computing system. The computing system includes a circuit board including an electronic component, another circuit board including another electronic component, wherein the circuit boards are positioned alongside each other, and an expandable duct. The expandable duct is positioned between the circuit boards and is in contact with at least one of the electronic components, and the expandable duct forms a path through the computing system that is fluidly connected to the pump and the heat exchanger to form a closed loop.

According to one embodiment of the present disclosure, a method of operating a heat transfer system for a computing system includes reading outputs of contact sensors positioned in the computing system, determining that there is a lack of contact of an expandable duct against at least one of the contact sensors based on the reading of the outputs of the contact sensors which indicates inadequate contact between the expandable duct and an electronic component of a circuit board in the computing system, and decreasing flow of a cooling fluid through the expandable duct in response to determining that there is a lack of contact of the expandable duct. The method also includes reading output of a temperature sensor of the electronic component, determining that the temperature of the electronic component is higher than an electronic component temperature threshold based on the reading of the output of the temperature sensor, and increasing flow from a cooling fluid pump in response to determining that the temperature of the electronic component is higher than the electronic component temperature threshold.

### BRIEF DESCRIPTION OF THE DRAWINGS

FIG. 1 is a perspective view of a heat transfer system, in accordance with an embodiment of the present disclosure.

FIG. 2 is an exploded perspective view of a computing system, in accordance with an embodiment of the present disclosure.

FIG. 3A is a cross-sectional view of the computing system along line A in FIG. 1, in accordance with an embodiment of the present disclosure.

FIG. 3B is a cross-sectional view of the computing system along line B in FIG. 1, in accordance with an embodiment of the present disclosure.

FIG. 4 is a side view of an expandable cooling duct, in accordance with an embodiment of the present disclosure.

FIG. 5 is a flowchart of a method of operating the heat transfer system, in accordance with an embodiment of the present disclosure.

### DETAILED DESCRIPTION

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship.

The following definitions and abbreviations are to be used for the interpretation of the claims and the specification. As used herein, the terms “comprises,” “comprising,” “includes,” “including,” “has,” “having,” “contains,” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing Figures. The terms “overlying,” “atop,” “on top,” “positioned on,” or “positioned atop” mean that a first element, such as a first structure, is present on a second element, such as a second structure, wherein intervening elements such as an interface structure can be present between the first element and the second element.

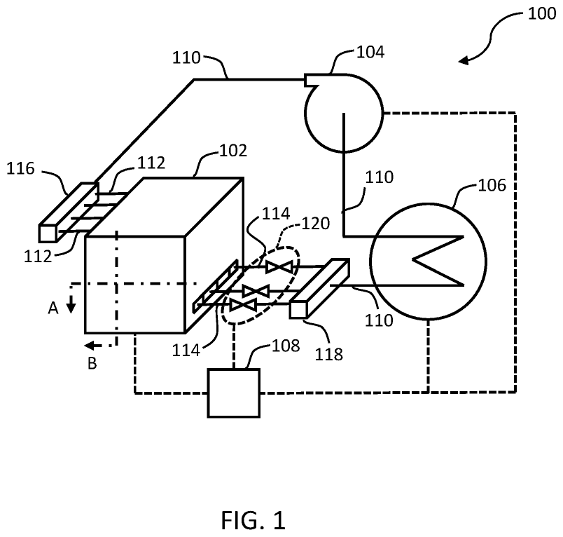

FIG. 1 is a perspective view of heat transfer system 100. In the illustrated embodiment, heat transfer system 100 includes computing system 102, pump 104, heat exchanger 106, and controller 108 that are fluidly connected to one another via lines 110. Lines 110 carry cooling fluid, for example, water, between the components of heat transfer system 100 in a closed loop. This cooling fluid is pressurized in pump 104, heated in computing system 102, and cooled in heat exchanger 106 so that heat can be removed from computing system 102.

In the illustrated embodiment, computing system 102 has several parallel flow paths (as indicated by inlets 112 and outlets 114), so inlet manifold 116 is positioned upstream of computing system 102, and outlet manifold 118 is positioned downstream of computing system 102. In order to control flow through the parallel flow paths of computing system 102, valves 120 are positioned between each outlet 114 and outlet manifold 118. Valves 120 are communicatively connected to and controlled by controller 108. Similarly, pump 104 is communicatively connected to and controlled by controller 108. Controller 108 is also communicatively connected to sensors placed throughout heat transfer system 100, for example, in computing system 102 and heat exchanger 106. Controller 108 can automatically adjust parameters of heat transfer system 100 (e.g., the output of pump 104 and the flow through valves 120) based on data from the sensors and predetermined operating thresholds (e.g., the maximum allowable temperature of the cooling fluid and/or electronic components).

Depicted in FIG. 1 is one embodiment of the present disclosure, to which there are alternative embodiments. For example, heat exchanger 106 can be directly upstream of computing system 102, and pump 104 can be directly downstream of computing system 102. For another example, there can be more than three parallel flow paths through computing system 102. For another example, controllable flow valves can be positioned between inlet manifold 116 and inlets 112 instead of or in addition to valves 120.

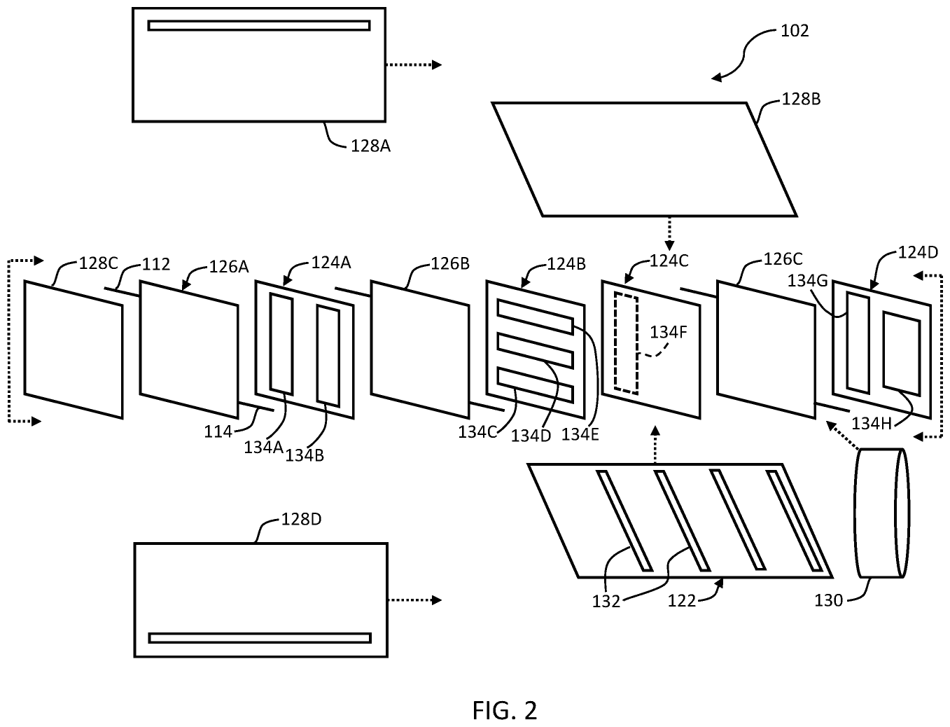

FIG. 2 is an exploded perspective view of computing system 102. In the illustrated embodiment, computing system 102 includes motherboard 122, circuit boards 124A-124D (collectively “circuit boards 124”), ducts 126A-126C (collectively “ducts 126”), constraining walls 128A-128D (collectively “constraining walls 128”), and restrictor band 130. When assembled, circuit boards 124 are plugged into the array of card connectors 132 on motherboard 122 so circuit boards 124 are positioned alongside each other (i.e., extending in parallel planes to one another and perpendicular to motherboard 122).

In the illustrated embodiment, circuit boards 124 include electronic components 134A-134H (collectively “electronic components 134”), respectively. Circuit boards 124 can have different functions (e.g., at least some can be memory cards) and/or configurations from one another, so the sizes, locations, and orientations of electronic components 134 can vary board-to-board. In addition, electronic components 134 can generate heat during operation, and this heat can be removed by operating heat transfer system 100 (shown in FIG. 1). Thereby, ducts 126 are positioned between circuit boards 124 (e.g., when they are empty), and then ducts 126 are filled with cooling fluid. Ducts 126 are made from expandable, stretchable, and/or flexible materials (such as, for example, high density polyethylene, low density polyethylene, linear low density polyethylene, polypropylene, and polyvinyl chloride), so ducts 126 come into contact with and conform to electronic components 134 when filled. The cooling fluid flows through ducts 126 via inlets 112 and outlets 114, so there are several parallel flow paths to evacuate heat from computing system 102.

In the illustrated embodiment, electronic component 134H would not benefit from contact with duct 126C, which can be for a reason such as fragility, lack of heat generation, or need for heat retention. Thereby, restrictor band 130 can be positioned around a portion of duct 126C to locally prevent expansion. Restrictor band 130 can be, for example, an elastomeric rubber component. However, to generally prevent over expansion of ducts 126 and keep ducts 126 in place, constraining walls 128A-128D (collectively “constraining walls 128”) are strategically positioned in computing system 102. For example, constraining walls 128 are positioned where there is an open side around one or more ducts 126 to form a housing over motherboard 122. Thereby, constraining walls 128 assist in maintaining contact between ducts 126 and electronic components 134.

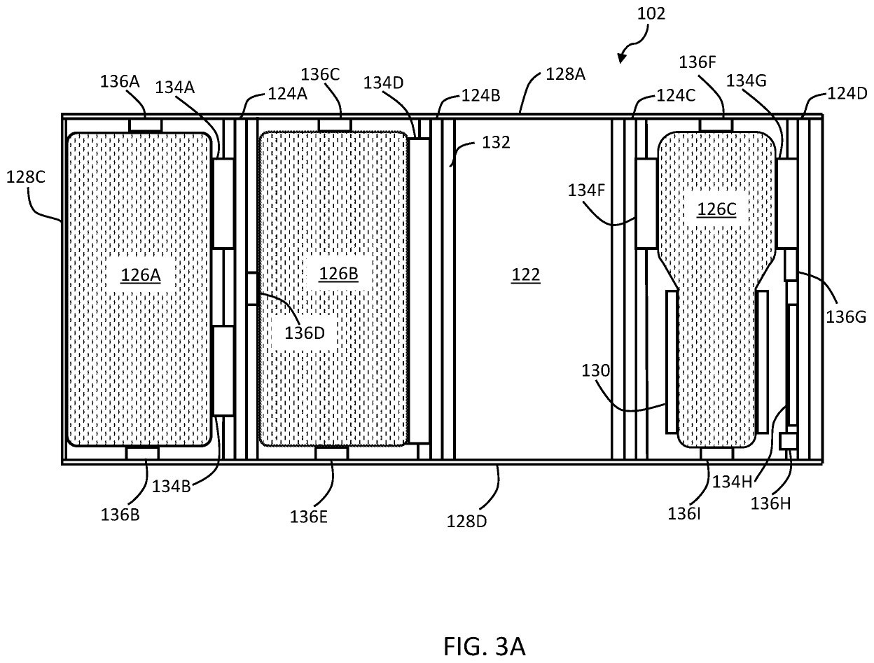

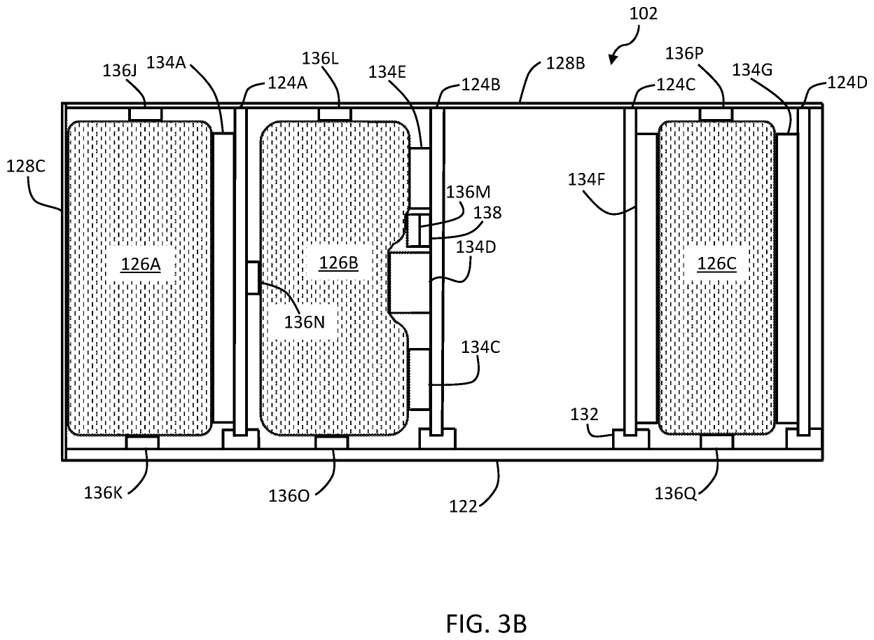

FIG. 3A is a cross-sectional view of computing system 102 along line A in FIG. 1. FIG. 3B is a cross-sectional view of computing system 102 along line B in FIG. 1. FIGS. 3A and 3B will be discussed in conjunction with one another. It should be noted that ducts 126 have been illustrated such that their sides are straight unless otherwise impinged upon. While ducts 126 could be constructed in such a manner that would encourage this quality (i.e., made of six flat sections welded together), ducts 126 could be constructed as a single piece (à la a balloon). In such embodiments, ducts 126 may bulge further to more generously fill the space. This may cause ducts 126 to contact motherboard 122, circuit boards 124, and/or constraining walls 128 more than is shown in FIGS. 3A and 3B.

In the illustrated embodiment, duct 126A is positioned between motherboard 122, circuit board 124A, and constraining walls 128A-128D; duct 126B is positioned between motherboard 122, circuit boards 124A and 124B, and constraining walls 128A, 128B, and 128D; and duct 126C is positioned between motherboard 122, circuit boards 124C and 124D, and constraining walls 128A, 128B, and 128D. Duct 126C can cool both electronic components 134F and 134G despite them being on circuit boards 124C and 124D, respectively, since circuit boards 124C and 124D face each other. On the other hand, because there are no electronic components 134 between circuit boards 124B and 124C, there isn't a duct 126 positioned between circuit boards 124B and 124C. In some embodiments, a duct 126 may be placed in between circuit boards 124B and 124C but restrictor bands 130 may be positioned around it. This would prevent unnecessary expansion of the duct 126 to preserve its lifespan, but allow it to be plumbed in during initial assembly in case the configuration of circuit boards 124 was changed later on.

In the illustrated embodiment, computing system 102 includes sensors 136A-136Q (collectively “sensors 136”). Sensors 136 are positioned on motherboard 122, circuit boards 124, and constraining walls 128, respectively. Sensors 136 can detect contact with ducts 126, which can be read by controller 108 (shown in FIG. 1). During operation of heat transfer system 100 (shown in FIG. 1), ducts 126 expand and come into contact with at least some of sensors 136. For example, duct 126B contacting sensors 136C, 136D, 136E, 136L, 136M (which is positioned on pedestal 138), 136N, and 136O can indicate to controller that duct 126B is properly conforming to the geometry that constrains it. However, as stated previously, restrictor band 130 prevents duct 126C from contacting electronic component 134H. If restrictor band 130 fails, duct 126C will expand and contact at least one of sensors 136G and 136H, which can alert controller 108 of the problem. In some embodiments, sensors 136 can also sense temperature. This data can also be read by controller 108 and added to any other temperature sensors present in heat transfer system 100 (e.g., sensors that are installed on circuit boards 124 to measure temperatures of electronic components 134, for example, sensor 136G on circuit board 124D, and/or sensors that are in direct contact with the cooling fluid such as, for example, at pump 104, heat exchanger 106, and/or valves 120, shown in FIG. 1 to measure temperatures of the cooling fluid).

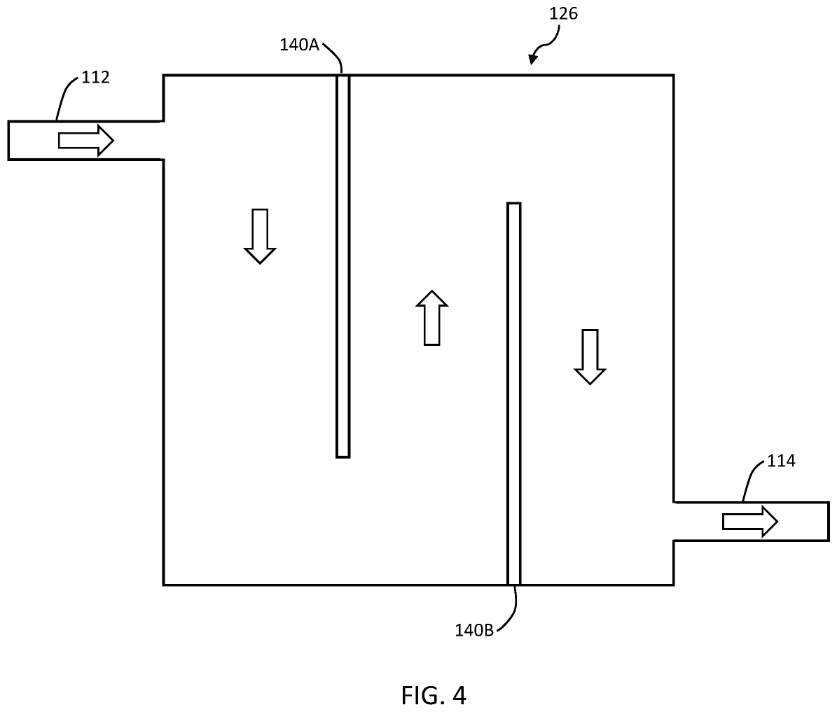

FIG. 4 is a side view of duct 126. Because ducts 126 are expandable, they can all be manufactured the same regardless of their placement in computing system 102 or the configurations of circuit boards 124 and electronic components 134 (shown in FIG. 2). Thereby, duct 126 can represent any of ducts 126A-126C.

In the illustrated embodiment, duct 126 includes dividers 140A-140B (collectively “dividers 140”). Dividers 140 can extend across the interior of duct 126, and dividers 140 can be additional material added to duct 126 or they can be formed by local melting/welding of the sides of duct 126 together. Dividers 140 define a flow path for the cooling fluid from inlet 112 to outlet 114 (as indicated by the arrows) to increase the uniformity of flow in duct 126, which increases the cooling capacity at the corners of duct 126 opposite from inlet 112 and outlet 114.

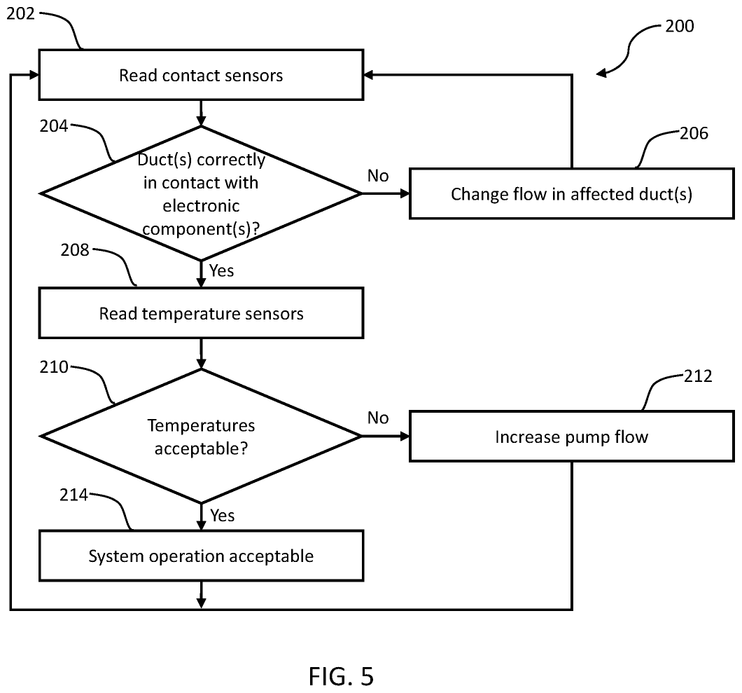

FIG. 5 is a flowchart of method 200 of operating heat transfer system 100. During the discussion of method 200, references may be made to components and features described previously with respect to FIGS. 1-4. Method 200 can be performed regularly or continuously to ensure proper operation of heat transfer system 100 since the demands on computing system 102 can change rapidly, which can change the amount of cooling required.

In the illustrated embodiment, method 200 starts at operation 202 where the contact sensors (i.e., sensors 136) are read by controller 108. At operation 204, controller 108 determines whether ducts 126 are contacting the correct electronic components 134 based on the reading of sensors 136. If there is not contact where there should be or if there is contact where there shouldn't be, then the flow in the affected ducts is adjusted at operation 206. For example, if there was insufficient contact of a duct 126, the corresponding valve 120 can be restricted (e.g., closed to an extent). For another example, if there was inappropriate contact of a duct 126, the corresponding valve 120 can be expanded (e.g., opened to an extent). However, if the contact was correct, then method 200 moves to operation 208.

In the illustrated embodiment, at operation 208, the temperature sensors (e.g., sensors 136) are read by controller 108. At operation 210, controller 108 determines whether the temperatures of electronic components 134 cooled by ducts 126 are acceptable based on the reading of the temperature sensors. If any of the temperatures (either direct measurements of electronic components 134 and/or proxy measurements thereof from ducts 126) is above a threshold, then the flow from pump 104 is increased (e.g., by increasing pump speed) at operation 212. However, if the temperatures were below the threshold, then method 200 moves to operation 214 where controller 108 determines that the operation of heat transfer system 100 is acceptable.

Depicted in FIG. 5 is one embodiment of the present disclosure, to which there are alternative embodiments. For example, sensors 136 can be non-binary in that they can measure the force of contact (e.g., pressure). For another example, instead of or in addition to restricting or expanding the corresponding valve 120 at operation 206, pump flow can be adjusted. For another example, instead of or in addition to increasing pump flow at operation 212, the valves 120 for the non-affected ducts 126 can be restricted to effectively increase flow in the affected duct 126. The latter two alternative embodiments can be aided by the initial alternative embodiment in that controller 108 would be able to determine how close to the acceptable thresholds each duct 126 was when deciding how remedy the unacceptable operation of a duct 126.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computing system comprising:
a motherboard comprising an array of card connectors;
a plurality of circuit boards connected to the array of card connectors, wherein the plurality of circuit boards include a plurality of electronic components;
a plurality of constraining walls positioned around the plurality of circuit boards to form a housing over the motherboard;
a plurality of expandable ducts, wherein:
one of the plurality of expandable ducts is positioned in contact with one of the plurality of electronic components and constrained by a constraining wall when expanded;
each of the plurality of expandable ducts includes an inlet, an outlet, and a fluid flow path from the inlet to the outlet that is parallel to other fluid flow paths of other expandable ducts.

2. The computing system of claim 1, further comprising an inlet manifold fluidly connected to each inlet, and an outlet manifold fluidly connected to each outlet.

3. The computing system of claim 2, wherein each of the plurality of expandable ducts is configured to be expanded by a cooling liquid.

4. The computing system of claim 3, further comprising a control system comprising:
a contact sensor positioned on one of the motherboard, one of the plurality of circuit boards, or one of the plurality of constraining walls, wherein the contact sensor is configured to detect expansion of one of the plurality of expandable ducts; and
a temperature sensor configured to measure temperature of the one of the plurality of electronic components in contact with the one of the plurality of expandable ducts and/or temperature of the cooling liquid.

5. The computing system of claim 4, wherein the control system further comprises a plurality of adjustable valves positioned between each of the outlets and the outlet manifold to control flow of the cooling liquid through each of the plurality of expandable ducts, respectively.

6. The computing system of claim 1, wherein at least one of the plurality of expandable ducts includes a divider configured to divert the fluid path between the inlet and the outlet.

7. The computing system of claim 1, wherein each of the plurality of expandable ducts contacts at least one of the plurality of electronic components when expanded.

8. The computing system of claim 7, wherein at least one of the plurality of expandable ducts contacts at least one of the plurality of electronic components from at least two circuit boards when expanded.

9. The computing system of claim 1, wherein at least two of the plurality of circuit boards have different locations for their electronic components, respectively.

10. A heat transfer system comprising:
a pump;
a heat exchanger fluidly connected to the pump; and
a computing system comprising:
a first circuit board including a first electronic component;
a second circuit board including a second electronic component, wherein the second circuit board is positioned alongside the first circuit board; and
a first expandable duct positioned between the first circuit board and the second circuit board that is in contact with at least one of the first electronic component and the second electronic component, the first expandable duct forming a first path through the computing system that is fluidly connected to the pump and the heat exchanger to form a closed loop.

11. The heat transfer system of claim 10, further comprising a control system comprising:
a first contact sensor in the computing system to measure expansion of the first expandable duct;
a first temperature sensor positioned on one of the first circuit board or the second circuit board configured to measure temperature of one of the first electronic component or the second electronic component, respectively, or positioned in the closed loop configured to measure temperature of a cooling fluid; and
a first adjustable valve in the closed loop configured to control flow of the cooling fluid through the first expandable duct.

12. The heat transfer system of claim 11, wherein the computing system further comprises:
a third circuit board including a third electronic component; wherein the third circuit board is positioned alongside the second circuit board;
a fourth circuit board including a fourth electronic component, wherein the fourth circuit board is positioned alongside the third circuit board; and
a second expandable duct positioned between the third circuit board and the fourth circuit board that is in contact with at least one of the third electronic component and/or the fourth electronic component, the second expandable duct forming a second path through the computing system that is parallel to the first path and is fluidly connected to the pump and the heat exchanger as part of the closed loop.

13. The heat transfer system of claim 12, wherein the control system further comprises:
a second contact sensor in the computing system to measure expansion of the second expandable duct; and
a second adjustable valve in the closed loop configured to control flow of the cooling fluid through the second expandable duct.

14. The heat transfer system of claim 12, further comprising:
a first manifold in the closed loop that is fluidly connected to the first path and the second path upstream of the computing system; and
a second manifold in the closed loop that is fluidly connected to the first path and the second path downstream of the computing system and the first adjustable valve.

15. The heat transfer system of claim 12, further comprising:
a second temperature sensor positioned on the second circuit board and configured to measure the temperature of the second electronic component;
wherein the first temperature sensor is positioned on the first circuit board and is configured to measure the temperature of the first electronic component.

16. The heat transfer system of claim 11, wherein the control system further comprises a second contact sensor in the computing system opposite to the first contact sensor to measure expansion of the first expandable duct.

17. The heat transfer system of claim 11, wherein the control system further comprises a pump flow controller configured to control flow of the cooling fluid through the pump.

18. The heat transfer system of claim 10, wherein the computing system further comprises a constraining wall in contact with the first expandable duct to configured to constrain expansion of the first expandable duct to encourage contact of the first expandable duct and the at least one of the first electronic component or the second electronic component.

19. The heat transfer system of claim 10, wherein the first expandable duct includes a divider configured to divert the first path between an inlet and an outlet.

20. A method of operating a heat transfer system for a computing system, the method comprising:
reading outputs of a plurality of contact sensors positioned in the computing system;
determining that there is a lack of contact of an expandable duct against at least one of the plurality of contact sensors based on the reading of the outputs of the plurality of contact sensors which indicates inadequate contact between the expandable duct and an electronic component of a circuit board in the computing system;
decreasing flow of a cooling fluid through the expandable duct in response to determining that there is a lack of contact of the expandable duct;
reading output of a temperature sensor of the electronic component;
determining that the temperature of the electronic component is higher than an electronic component temperature threshold based on the reading of the output of the temperature sensor; and
increasing flow from a cooling fluid pump in response to determining that the temperature of the electronic component is higher than the electronic component temperature threshold.
